(19) United States
(12) Patent Application Publication
(10) Pub. No.: US 2025/0174614 A1
(43) Pub. Date: May 29, 2025

(54) DISPLAY PANEL USING METAMATERIALS FOR UNDER-DISPLAY IMAGE SENSORS, AND METHOD FOR MANUFACTURING THE SAME AND DISPLAY APPARATUS COMPRISING THE SAME

(71) Applicant: IUCF-HYU (INDUSTRY-UNIVERSITY COOPERATION FOUNDATION HANYANG UNIVERSITY), Seoul (KR)

(72) Inventors: Myunghoo LEE, Seoul (KR); Jaegang JO, Seoul (KR); Haejun CHUNG, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 18/910,146

(22) Filed: Oct. 9, 2024

Related U.S. Application Data
(63) Continuation of application No. PCT/KR2024/010508, filed on Jul. 19, 2024.

(30) Foreign Application Priority Data
Nov. 27, 2023 (KR) 10-2023-0166632

(51) Int. Cl. H01L 25/16; B82Y 20/00; B82Y 40/00; H01L 27/146

(52) U.S. Cl. CPC H01L 25/167; B82Y 20/00; B82Y 40/00; H10F 39/8063

(57) ABSTRACT

The present disclosure relates to a display panel which maximizes light and reduces high-order light to obtain high-quality images and/or videos by reducing the influence of diffracted light using metamaterials for UDC (Under Display Camera), a method for manufacturing the same, and a display device comprising the same, in which a metamaterial designed using the adjoint optimization method is formed on the lower part of the display substrate with a periodic arrangement structure.

### TECHNICAL FIELD

This invention was supported by 1) Project Unique Number 1711198310 and Project Number RS-2023-00261368, 2) Project Unique Number 1711198102 and Project Number RS-2023-00253914, 3) Project Unique Number 1711193603 and Project Number 2020-0-01373, 4) Project Unique Number 202400000001916 and Project Number RS-2024-00338048, 5) Project Unique Number 202400000002174 and Project Number RS-2024-00412644 funded by the Ministry of Science, ICT. Also, this invention was supported by Project Unique Number 202300000000488 and Project Number 1415180303 funded by the Ministry of Trade, Industry and Energy. And, this invention was supported by Project Unique Number 202400000002645 and Project Number RS-2024-00332210 funded by the Ministry of Culture, Sports and Tourism. The present disclosure relates to a display panel using a metamaterial for under display image sensors, a method of manufacturing the same, and a display device comprising the same, and more particularly to a technique for reducing the effect of diffracted light by using a metamaterial for an under display camera (UDC) to maximize light and reduce diffracted light of high order to obtain high quality images and/or moving images.

### BACKGROUND ART

Under Display Camera (UDC) technology is a technology that hides a camera or Time of Flight (ToF) sensor under a display panel to eliminate visual obstructions such as display holes and notches. The UDC technology is being touted as the next-generation display technology because the UDC technology is able to eliminate visual obstructions and maximize user immersion and maximize a panel area relative to the device's front surface area.

However, the display panel transmits light through periodically placed apertures, which delivers images deteriorated due to diffraction to the UDC. As a result, the image quality of UDC is much lower than cameras placed in conventional hole or notch structures.

In order to solve the problem of low-quality images by reducing such diffraction phenomenon, techniques have been proposed to reduce a conventional display pixel density (Pixel Per Inch), but the lower display pixel density PPI (Pixel Per Inch) has the limitation of causing a mosaic pattern (or screen door effect) on the display.

In addition, in order to solve the problem of low-quality images by reducing diffraction phenomena, technologies have been proposed to restore degraded images by additionally utilizing computer algorithms such as deep learning and GAN (generative adversarial network), but it is difficult to restore images and moving images in real-time due to additional computer operations. In addition, technologies have been proposed to improve the quality of images captured by UDC by adjusting the arrangement of existing display pixels, but the adjustment of the pixel arrangement affects the entire circuit of the display, lowering the intensity uniformity of the display.

Consequently, prior art has not been able to solve the problem of mosaic patterns appearing on the display due to low display pixel density (PPI) or the low intensity uniformity. Despite the development of many technologies to date and the benefits of using large screens, the aforementioned issues have prevented many companies from adopting UDC in mobile phones.

### DETAILED DESCRIPTION OF THE INVENTION

### Technical Problem

An object of the present disclosure is to present a meta-optical structure for reducing the influence of diffraction phenomena on images and/or moving images and an adjoint optimization method for designing the same.

An object of the present disclosure is to design a meta-surface by the adjoint optimization method to prevent diffraction from occurring in a UDC structure.

An object of the present disclosure is to propose a display panel that restores light to plane waves by placing a metasurface designed using the adjoint optimization method after the light has been diffracted by a periodic grating structure.

However, the technical problems to be solved by the present disclosure are not limited to the above problems and may be variously expanded without departing from the technical spirit and scope of the disclosure.

### Technical Solution

According to an embodiment of the present disclosure, a display panel using a metameterial for a under display image sensor includes a metameterial designed using an adjoint optimization method and formed on a rear portion of a display substrate having a periodic arrangement structure.

The present disclosure provides a display device including the display panel.

According to an embodiment of the present disclosure, a method for manufacturing a display panel using a metameterial for an under-display image sensor includes forming a metameterial designed using an adjoint optimization method on a rear portion of a display substrate having a periodic arrangement structure.

### Advantageous Effects of the Invention

According to the embodiments of the present disclosure, by designing a metasurface through an adjoint optimization method to maximize the intensity of 0-th-order diffracted light and reduce the intensity of higher-order light, the image and/or moving-image quality deteriorated due to the diffraction phenomenon, which is a fundamental problem of UDC technology, may be significantly improved.

According to the embodiments of the present disclosure, a display structure including a meta-optical structure capable of improving the quality of an image and/or a video in real time while maintaining a high pixel density may be proposed.

According to the embodiments of the present disclosure, the quality of an image and/or a moving image may be improved without an additional computational process such as an artificial intelligence algorithm utilized for image improvement of UDC technology, thus making it possible to capture high-quality images and/or moving images in real time. In addition, excellent image and/or moving image quality may be obtained even at a higher PPI (Pixels Per Inch) compared to the current UDC technology.

However, the effects of the present disclosure are not limited to the above effects and may be expanded in various ways without departing from the technical spirit and scope of the present disclosure.

### DESCRIPTION OF THE DRAWINGS

FIGS. 1A and 1B illustrate schematic diagrams for describing a process of the adjoint optimization method for controlling diffraction phenomenon according to an embodiment of the present disclosure.

FIG. 2 illustrates a structural diagram of a display panel on a UDC according to an embodiment of the present disclosure.

FIG. 3 illustrates a cross-sectional view of a display panel including a metamaterial according to an embodiment of the present disclosure.

FIGS. 4A to 4I illustrate graphs of the results of a function (Modulation Transfer Function) that measures the resolution of a camera according to an embodiment of the present disclosure.

### BEST MODE

Advantages and features of the present disclosure and methods for achieving them will be apparent with reference to embodiments described below in detail in conjunction with the accompanying drawings. However, the present disclosure is not limited to the embodiments disclosed below, but may be implemented in various forms, and these embodiments are to make the disclosure of the present disclosure complete, and are provided so that this disclosure will be thorough and complete and will fully convey the scope of the invention to those of ordinary skill in the art, which is to be defined only by the scope of the claims.

The terminology used herein is for the purpose of describing particular embodiments only and is not intended to be limiting of the inventive concept. The singular expressions include plural expressions unless the context clearly dictates otherwise. In this specification, the terms “comprises” and/or “comprising” are intended to specify the presence of stated features, integers, steps, operations, elements, parts or combinations thereof, but do not preclude the presence or addition of steps, operations, elements, parts, or combinations thereof.

Unless defined otherwise, all terms (including technical and scientific terms) used herein have the same meanings as commonly understood by one of ordinary skill in the art to which this invention belongs. Further, unless explicitly defined to the contrary, the terms defined in a generally-used dictionary are not ideally or excessively interpreted.

Hereinafter, preferred embodiments of the present disclosure will be described in detail with reference to the accompanying drawings. The same reference numerals are used for the same components in the drawings, and duplicate descriptions of the same components are omitted.

The present disclosure relates to the use of metamaterials for under display cameras (UDCs) to maximize light, reduce the effects of diffracted light to obtain high quality images and/or videos, and to reduce high order light.

The present disclosure proposes an inverse metasurface that restores diffraction due to a periodic aperture of a display to improve image quality. The inverse metasurface is a metasurface that converts high-order diffraction waves whose propagation direction has changed due to diffraction into 0-th-order diffraction waves whose propagation direction is the same before diffraction. The present disclosure designs the inverse metasurface using the adjoint optimization method, which is a high-performance free-form metasurface design method. In addition, it was confirmed through simulation that the inverse metasurface improves the power ratio of the 0-th-order diffraction wave in the UDC structure from the existing 59.59% to 88.98%.

The meta-optical structure functions to maximize the power of the 0-th-order diffracted light and reduce the power of the high-order light to reduce the diffraction effect caused by the display panel. Through this, the image quality degradation problem caused by the diffraction phenomenon occurring in the UDC may be solved.

The present disclosure performs optimization of the meta-optical structure using the adjoint method. Although specific values may be utilized in this optimization process, the values are determined in the actual implementation and design process and may be adjusted to obtain the optimal image quality.

The various descriptions, functions, procedures, proposals, and methods described in the present disclosure may be applied to various devices that photograph and measure by placing an under-display image sensor (camera and/or sensor).

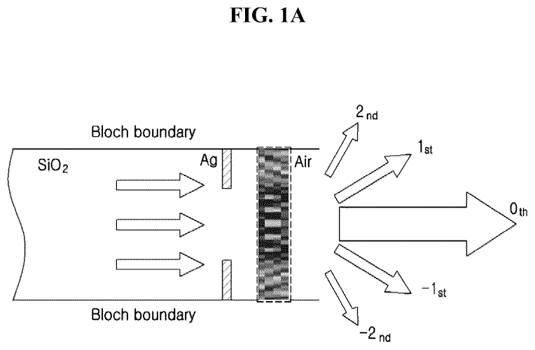

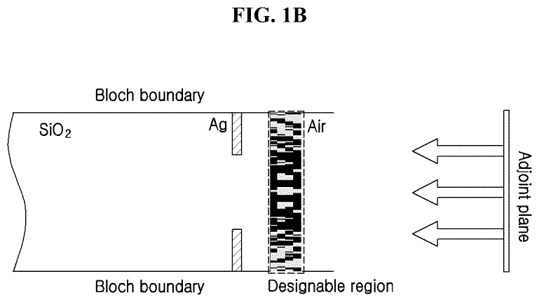

Hereinafter, the present disclosure will be described in detail with reference to FIGS. 1 to 4.

FIGS. 1A and 1B illustrate schematic diagrams for describing a process of the adjoint optimization method for controlling diffraction phenomenon according to an embodiment of the present disclosure.

FIGS. 1A and 1B illustrate diagrams for describing a process of designing metamaterial that maximizes the diffracted light of zero-order and reduces diffracted light of high-order according to an embodiment of the present disclosure using the adjoint optimization method. More specifically, FIG. 1A is illustrated to describe forward propagation simulation, and FIG. 1B is illustrated to describe the reverse propagation simulation.

When light passes through periodically arranged apertures, as the number of apertures increases, except for the peak light of the diffraction order (0-th), the remaining light disappears due to destructive interference or the power of light decreases, as shown in FIG. 1A due to destructive interference.

In the case of light diffraction, even if only 20 or more apertures of the same shape are periodically arranged, the result is almost the same as that of infinitely arranged apertures. Therefore, in the case of a UDC display in which 30 or more identically shaped pixel structures are arranged, infinitely periodically arranged apertures may be assumed.

Therefore, the present disclosure uses the Bloch boundary condition to assume periodically arranged apertures. Since the Bloch boundary condition assumes infinitely periodically repeated arrangements, only one unit segment is simulated, and the result may be the same as that of a structure in which the unit segment is infinitely repeated.

In this simulation result, only the peak light of the diffraction order remains, and a metamaterial that controls the power of the peak light of the diffraction order is designed.

A metamaterial refers to an optical structure capable of changing the phase, amplitude, and polarization of light through a change in effective refractive index. In the present disclosure, an adjoint optimization method is proposed to design a metamaterial capable of reducing the influence of the diffraction phenomenon on images and/or moving images.

The adjoint optimization method is an optimization algorithm that calculates a change in the Figure of Merit of the entire design area with only two simulations (forward propagation and backward propagation) through the concepts of Lorenz isotropy and equivalent dipole for a target design area, and designs a structure that achieves maximization or minimization of the target figure of merit through this.

More specifically, the backpropagation design technique sets the Figure of Merit (FoM) to be maximized through the structure to be designed, and calculates the derivative of the Figure of Merit (FoM) through two simulations including forward simulation and adjoint simulation. Then, through the process of repeating these two simulations and the gradient descent method, the amount of change in the Figure of Merit (FoM) according to a change in the permittivity or permeability of the design area may be predicted, and based on this, a structure that maximizes or minimizes the Figure of Merit may be designed. In this case, the source of the backpropagation, that is, the adjoint source, is determined based on the amount of change in the Figure of Merit (FoM) when a previously specified change in permittivity occurs in each pixel within the design area. Through this repeating process, the amount of change in the Figure of Merit may be calculated when a material is placed in the design area.

Referring to FIG. 1, in order to assume a display structure with periodical arrangements, a block boundary condition is used to simulate one “d” unit segment, and the result may be obtained as the same result as in a structure where the unit segment is infinitely repeated.

In this case, the Figure of Merit to be maximized is as follows [Equation 1].

$$FoM = {P}_{00} - {\sum }_{ij} {P}_{ij} ( {i}^{2} + {j}^{2} ) . \qquad [ Equation 1 ]$$

In [Equation 1], Poo denotes the power of propagation of diffraction of 0-th order, and Pᵢⱼ denotes the power of propagation of diffraction order corresponding to the i-th and j-th along the x-axis and y-axis, respectively. Here, “i” and “j” are determined during the actual implementation and design process, and may be adjusted to obtain the optimal image quality.

By optimizing the structure that maximizes the Figure of Merit of [Equation 1], the meta-optical structure that maximizes the intensity of the diffracted light of zero-order and reduces the intensity of the diffracted light of the high order presented in the present disclosure may be obtained.

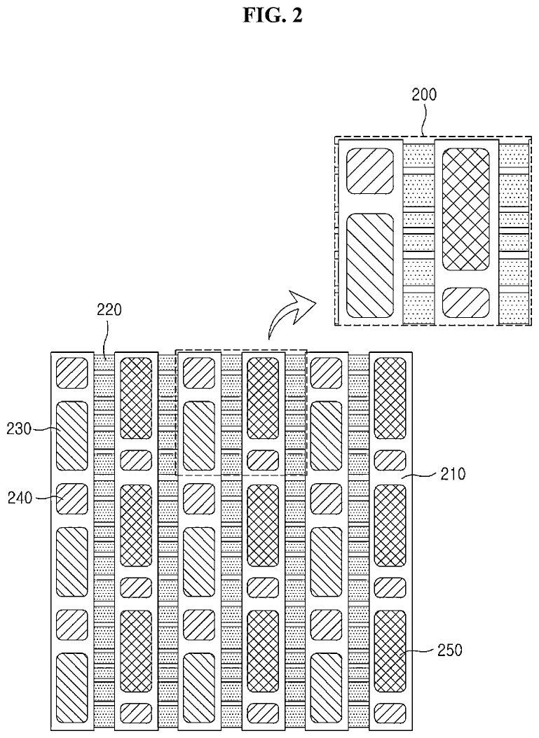

FIG. 2 illustrates a structural diagram of a display panel on a UDC according to an embodiment of the present disclosure.

FIG. 2 is a drawing illustrating a display panel on a UDC according to an embodiment, which may be changed during the actual implementation and design process.

A display according to the embodiment of the present disclosure includes a display structure as in FIG. 2.

Referring to FIG. 2, a display structure may include a unit pixel 200, and the unit pixel 200 may be composed of an absorptive pixel define layer 210, a transparent electrode 220, and an “R” subpixel 230, a “G” subpixel 240, and a “B” subpixel 250. The present disclosure aims to reduce the influence of light diffraction on images and/or moving images by using a metamaterial designed using the adjoint optimization method in a display structure having periodical arrangements. In addition, the present disclosure may obtain a meta-optical structure that maximizes the power of light of zero-order diffraction and reduces the power of light of high-order diffraction by the adjoint optimization method described in the embodiment for all display structures in which pixels are periodically arranged.

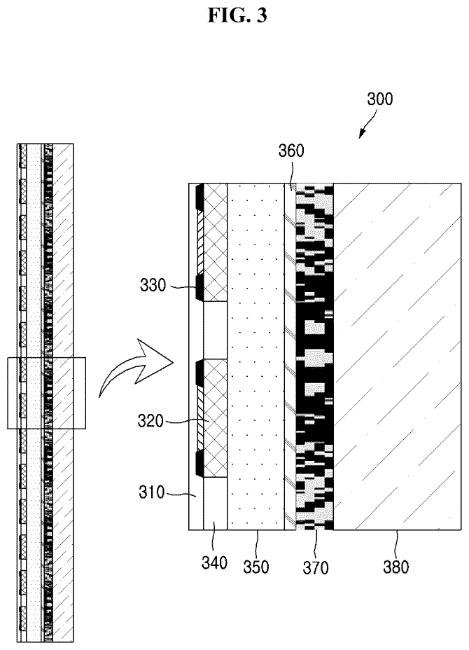

FIG. 3 illustrates a cross-sectional view of a display panel including a metamaterial according to an embodiment of the present disclosure.

Referring to FIG. 3, metasurfaces optimized by the adjoint optimization method according to an embodiment of the present disclosure may be disposed between a display panel and a camera lens and/or a sensor.

The structure of metamaterial optimized by a method presented in the embodiment of the present disclosure may be disposed between the display panel and the camera lens and/or the sensor. The structure functions to maximize the power of diffracted light of 0-th order and reduce the power of the diffracted light of high order to reduce the diffraction effect caused by the display panel.

In regard to a unit pixel 300 in the display panel in FIG. 3, there is an encapsulation layer 310 that protects LEDs of a display, and red, green, and blue subpixels are disposed on a pixel driving circuit 320 in the encapsulation layer 310, and the subpixels are separated by absorptive pixel separation layers 330. In addition, a transmitting area 340 is positioned between the pixel driving circuits 320. In addition, a metasurface 370 designed using the adjoint optimization method according to an embodiment of the present disclosure is positioned below a display substrate 350 and an optical adhesive layer 360, and a metasurface substrate 380 is positioned below the metasurface 370.

According to the present disclosure, the metasurface 370 may restore light generated in the transmitting area 340 by allowing the light to pass through without being distorted by diffraction.

According to the present disclosure, when simulation is performed after the metasurface designed using the adjoint optimization method is placed under a display with periodic arrangements as shown in FIG. 3, it is identified that the diffraction effect of propagation on the sensor or camera under the display is reduced.

The embodiment of the present disclosure may include a case where the metasurface is utilized not only for a camera that captures an image and/or a moving image under the display panel, but also for a sensor that performs measurement under the display. Here, the sensor includes all light-based sensors including a Time of Flight (ToF) sensor and an optical fingerprint recognition device.

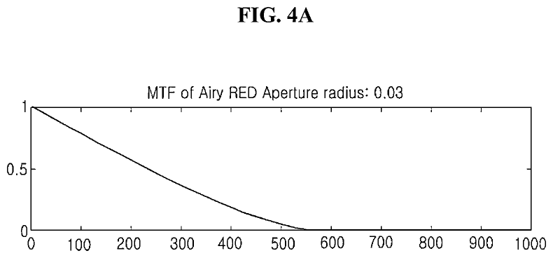

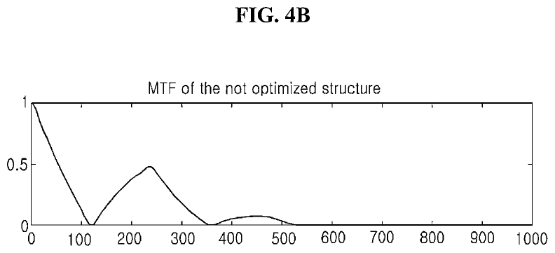

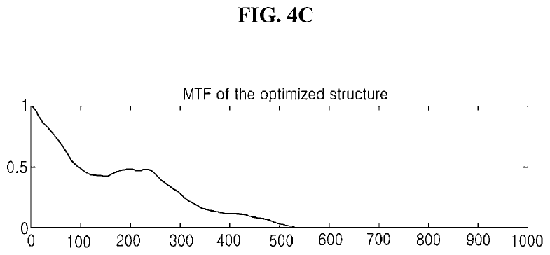

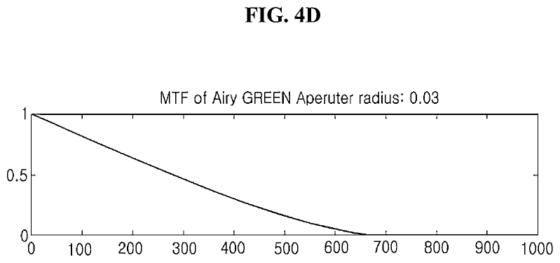

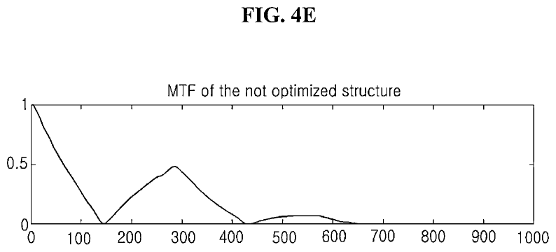

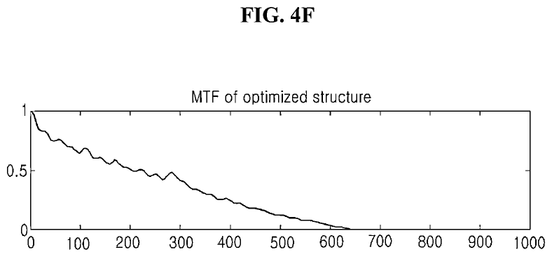

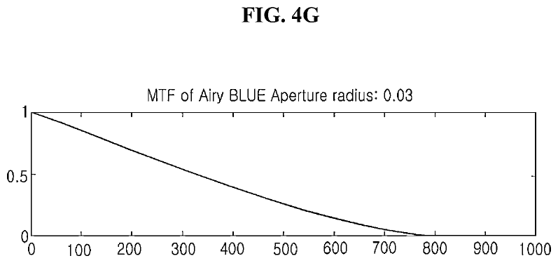

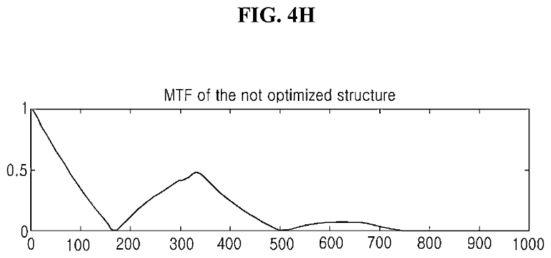

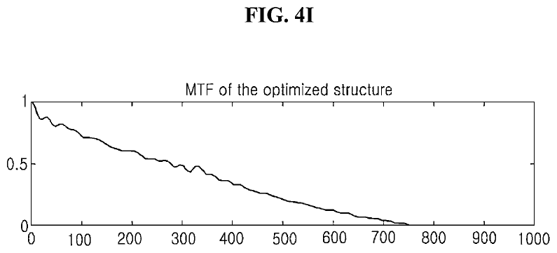

FIGS. 4A to 4I illustrate graphs of the results of a function (Modulation Transfer Function) that measures the resolution of a camera according to an embodiment of the present disclosure.

More specifically, FIG. 4A is a graph showing the experimental results of the MTF (Modulation Transfer Function) of the red light obtained by simulation in the absence of a diffraction structure, FIG. 4B is a graph showing the experimental results of the MTF of the red light obtained by simulation in the presence of a diffraction structure but without a metasurface, and FIG. 4C is a graph showing the experimental results of the MTF of the red light obtained by simulation in the presence of a diffraction structure including a metasurface.

In addition, FIG. 4D is a graph showing the experimental results of the MTF of the green light obtained by simulation in the absence of a diffraction structure, FIG. 4E is a graph showing the experimental results of the MTF of the green light obtained by simulation in the presence of a diffraction structure and without a metasurface, and FIG. 4F is a graph showing the experimental results of the MTF of the green light obtained by simulation in the presence of a diffraction structure including a metasurface.

In addition, FIG. 4G is a graph showing the experimental results of MTF of the blue light obtained by simulation in the absence of a diffraction structure, FIG. 4H is a graph showing the experimental results of MTF of the blue light obtained by simulation in the absence of a metasurface, and FIG. 4I is a graph showing the experimental results of MTF of the blue light obtained by simulation in the presence of a diffraction structure including a metasurface.

Referring to FIGS. 4C, 4F, and 4I, it may be seen that even in the presence of a diffraction structure, if the metasurface is included, the resolution is almost identical to that in the absence of a diffraction structure, as shown in FIGS. 4A, 4D, and 4G.

Accordingly, it may be seen that the camera resolution of the UDC is significantly increased, and diffraction is suppressed by including the metasurface designed using the adjoint optimization method according to the embodiment of the present disclosure, thus obtaining a clear image and/or moving image without distortion.

The present disclosure proposes a propagation element designed using the adjoint optimization method to solve the diffraction phenomenon, which is a problem occurring in the UDC. Through the simulation described above, it may be seen that the metasurface designed using the adjoint optimization method effectively limits the diffraction due to propagation. Therefore, it is expected that the proposed metasurface may be used as a high-resolution under-display image sensor in various devices.

The system or apparatus described herein may be implemented with hardware components and software components and/or a combination of the hardware components and the software components. For example, the apparatus and components described in the embodiments may be implemented using one or more general-purpose or special purpose computers, such as, for example, a processor, a controller and an arithmetic logic unit (ALU), a digital signal processor, a microcomputer, a field programmable gate array (FPGA), a programmable logic unit (PLU), a microprocessor or any other device capable of executing and responding to instructions. The processing device may run an operating system (OS) and one or more software applications that run on the OS. The processing device also may access, store, manipulate, process, and create data in response to execution of the software. For convenience of understanding, one processing device is described as being used, but those skilled in the art will appreciate that the processing device includes a plurality of processing elements and/or multiple types of processing elements. For example, the processing device may include multiple processors or a single processor and a single controller. In addition, different processing configurations are possible, such as parallel processors.

The software may include a computer program, a piece of code, an instruction, or some combination thereof, for independently or collectively instructing or configuring the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. In particular, the software and data may be stored by one or more computer readable recording mediums.

The above-described methods may be embodied in the form of program instructions that may be executed by various computer means and recorded on a computer-readable medium. The computer readable medium may include program instructions, data files, data structures, and the like, alone or in combination. Program instructions recorded on the media may be those specially designed and constructed for the purposes of the inventive concept, or they may be of the kind well-known and available to those having skill in the computer software arts. Examples of computer readable recording media include magnetic media such as hard disks, floppy disks and magnetic tape, optical media such as CD-ROMs, DVDs, and magnetic disks such as floppy disks, Magneto-optical media, and hardware devices specifically configured to store and execute program instructions, such as ROM, RAM, flash memory, and the like. Examples of program instructions include not only machine code generated by a compiler, but also high-level language code that may be executed by a computer using an interpreter or the like. The hardware device described above may be configured to operate as one or more software modules to perform the operations of the present disclosure, and vice versa.

### MODE FOR INVENTION

Although the embodiments have been described by the limited embodiments and the drawings as described above, various modifications and variations are possible to those skilled in the art from the above description. For example, the described techniques may be performed in a different order than the described method, and/or components of the described systems, structures, devices, circuits, etc. may be combined or combined in a different form than the described method, or other components, or even when replaced or substituted by equivalents, an appropriate result may be achieved.

Therefore, other implementations, other embodiments, and equivalents to the claims are within the scope of the following claims.

1. A display panel using metameterial for a under display image sensor, comprising:
a metameterial designed using an adjoint optimization method and formed on a rear portion of a display substrate having a periodic arrangement structure.

2. The display panel of claim 1, wherein the metameterial includes a three-dimensional (3D) metamaterial or a two-dimensional (2D) metasurface.

3. The display panel of claim 2, wherein the metamaterial is formed as a metasurface on the rear portion of the display substrate and is configured to restore diffraction of light in a transmitting area, which is caused due to the periodic arrangement structure of the display substrate, into a plane wave.

4. The display panel of claim 3, wherein the metasurface is formed of a metamaterial that maximizes a Figure of Merit using the adjoint optimization method to maximize an intensity of diffracted light of zero-order and reduce an intensity of diffracted light of high-order.

5. The display panel of claim 1, wherein the adjoint optimization method is a method of setting a target performance of the metamaterial as a Figure of Merit, calculating a change in the Figure of Merit of a metamaterial through two simulations including forward simulation and adjoint simulation, and then designing a structure that achieves maximization or minimization of the Figure of Merit.

6. The display panel of claim 5, wherein the adjoint optimization method obtains a structure that maximizes the Figure of Merit using a gradient descent method by performing multiple iterations of a process consisting of the two simulations.

7. A display device comprising the display panel of claim 1.

8. The display device of claim 7, wherein the display panel includes a display structure in which panels are periodically arranged.

9. The display device of claim 7, wherein the display device includes the metamaterial designed using the adjoint optimization method and disposed between the display panel and a camera lens.

10. The display device of claim 7, wherein the display device includes the metamaterial designed using the adjoint optimization method and disposed between the display panel and a sensor.

11. The display device of claim 10, wherein the sensor is at least one of a ToF (Time of Flight) sensor, an optical fingerprint recognition device and an optical measuring device.

12. A method for manufacturing a display panel using metameterial for an under-display image sensor, comprising:
forming a metameterial designed using an adjoint optimization method on a rear portion of a display substrate having a periodic arrangement structure.

13. The method of claim 12, wherein the metameterial includes a three-dimensional (3D) metamaterial or a two-dimensional (2D) metasurface.

14. The method of claim 12, wherein the forming includes forming, on the rear portion of the display substrate, a structure of a metamaterial that restores diffraction of light in a transmitting area, which is caused due to the periodic arrangement structure of the display substrate, into a plane wave.

15. The method of claim 14, wherein the forming includes forming a metamaterial that maximizes a Figure of Merit using the adjoint optimization method between the display panel and an image sensor to maximize an intensity of diffracted light of zero-order and reduce an intensity of diffracted light of high-order.

16. The method of claim 12, wherein the forming includes using the adjoint optimization of setting a target performance of the metamaterial as a Figure of Merit, calculating a change in the Figure of Merit through two simulations including forward simulation and adjoint simulation, and then designing a structure that achieves maximization or minimization of the Figure of Merit.

17. The method of claim 16, wherein the forming includes forming the metamaterial designed using the adjoint optimization method of obtaining a structure that maximizes the Figure of Merit using a gradient descent method by performing multiple iterations of a process consisting of the two simulations.
